(19) United States
(12) Patent Application Publication
(10) Pub. No.: US 2008/0063947 A1
(43) Pub. Date: Mar. 13, 2008

(54) Hologram recording medium and hologram cartridge media

(75) Inventor: Shiro Hayashi, Ibaraki (JP)

Correspondence Address: BIRCH STEWART KOLASCH & BIRCH, PO BOX 747, FALLS CHURCH, VA, 22040-0747, US

(73) Assignee: HITACHI MAXELL, LTD.

(21) Appl. No.: 11/896,878

(22) Filed: Sep. 6, 2007

(30) Foreign Application Priority Data
Sep. 8, 2006 (JP) 2006-243902

(51) Int. Cl. G03F 1/00

(52) U.S. Cl. 430/2

(57) ABSTRACT

In a hologram recording medium and a hologram cartridge media accommodating therein the hologram recording medium, in order to fill a hologram recording material over substrates at every nook and corners of the latter, the hologram recording medium is constructed such that the hologram recording material such as photopolymer is filled between the top and bottom planar substrates. Further, a frame is interposed between the top and bottom substrates so as to ensure a hologram material filling space. Further, the frame has at least one notch portion formed in the inner peripheral part thereof, and the hologram recording material is filled in both notch portion and filling space. The notch portion is adapted to allow the hologram recording material to be uniformly spread over in the entire filling space so as to have a recording layer having a substantially uniform thickness.

### FIELD OF THE INVENTION

The present invention relates to a hologram recording medium having a predetermined structure and a hologram cartridge media accommodating the hologram recording medium.

### DESCRIPTION OF RELATED ART

These days, information recording mediums such as optical discs including the so-called DVD, and magnetic discs including a HDD have been developed for such a tendency that the recording capacity and the transfer rate become rapidly higher partly because of the influences of digital broad casting and digital high-definition televisions. Among them, a hologram recording medium is excellent in high recording capacity, high transfer rate and random accessibility, and accordingly, has gotten a lot of attention in these years, as a next generation archive recording medium to HD-DVD or Blue ray disc (which will be simply referred to as “BD”).

In order to increase the recording capacity of a conventional disc such as DVD or BD, there have been exemplified several approaches such as, increasing a number of laminated recording films, shortening the wavelength of laser for recording and reproduction or narrowing track width so as to decrease track pitches. However, these approaches have become their technical limitations.

The hologram recording medium which has recently gotten a lot of attention, utilizes optical interference or diffraction, and is capable of three-dimensionally recording an interference pattern between two beams which are so-called as a reference beam and an information (signal) beam.

The data recording initially converts original data into digital data consisting of only “0” and “1”, similarly to CD or DVD. The data converted into “0” and “1” is arranged in a page unit and then converted into two-dimensional monochromatic bar-code-like data by a spatial light modulator. A beam which has passed through the two-dimensional bar codes, is turned into an information beam including data, and then crosses the reference beam on an information recording material so as to be recorded on a hologram recording medium. Further, by changing the crossing angle between the reference beam and the information beam, different data can be recorded at the same position.

Meanwhile, upon data reproduction, only the reference beam is used. By causing the reference beam to be incident upon the hologram recording medium with the same angle as that upon the data recording, the recoded hologram serves as diffraction grating for extracting the recorded monochromatic data. The extracted monochromatic data is detected as page data represented as “0” and “1” by means of two-dimensional detector. By demodulating the data represented as “0” and “1”, the reproduction is completed.

In addition to the principle of recording and reproduction for a hologram recording medium of an angle multiplex type as stated above, there have been used hologram recording mediums of a shift multiplex type in which a position is shifted, and a wavelength multiplex type in which a wavelength of the laser beam is changed.

As sated above, difference data can be recorded at the same position on the hologram recording medium, that is, the data can be recorded in a page unit, and accordingly, a large recording capacity and a higher transfer rate can be expected therefrom, and thus, it is highly expected as a next generation large recording capacity recording medium.

FIG. 1 is an exploded schematic view illustrating a structure of a conventional hologram recoding medium disclosed in the publication of U.S. Pat. No. 6,671,073. In FIG. 1, a hologram recording medium 10 is composed of a top substrate 11, a photopolymer layer 12 in which information is recorded, a frame 13 and a bottom substrate 14. Among them, the frame 13 has such a function as to prevent a photopolymer material forming the photopolymer layer 12 from projecting from the side surfaces of the top and bottom substrates between which the photopolymer layer 12 is interposed. Further, the hologram recording medium 10 having the above-mentioned structure has a disc-like shape.

By the way, since the hologram recording medium 10 disclosed in the publication of U.S. Pat. No. 6,671,073 has a disc-like shape, if it is accommodated in a usual rectangular cartridge, there is caused such a disadvantage that there are presented spaces which are not occupied by the recording medium in the cartridge. That is, no recording medium is present in these spaces. In other words, the entire internal space of the cartridge cannot be effectively used in view of increasing the recording capacity. As to the recording and reproduction of a hologram recording medium, there is no point in the disc-like shape of the hologram recording medium, when recording and reproduction of data thereon is carried out without rotating the recording medium.

Thus, there may be considered a hologram recording medium having a polygonal (rectangular) shape. In general, during a production of a hologram recording medium, a photopolymer material is interposed in a predetermined quantity between a top substrate and a bottom substrate, which are then pressed against each other in order to flatten and spread out the photopolymer material up to a predetermined thickness.

However, it is difficult to uniformly spread out the photopolymer material having a high degree of viscosity over an entire substrate (at every nook and corner of the substrate) which is not disc-like but rectangular, in particular. Should the filling of the material at corners of the substrate be inferior, the recording capacity would be lost correspondingly, and as well, its optical characteristics would be lowered.

### BRIEF SUMMARY OF THE INVENTION

The present invention is devised in view of the above-mentioned problems, and accordingly, an object of the present invention is to provide a hologram recording medium in which a hologram recording material is uniformly filled over entire substrates at every nook and corner thereof.

To the end, according to the present invention, there is provided a hologram recording medium in which a hologram recording material such as photopolymer is filled between top and bottom planar substrates and in which a frame is provided for ensuring a filling space for the hologram recording material between the top and bottom planar substrates. Further, the frame has at least one notch portion formed in its inner peripheral part, and the hologram recording material is filled in both of the filling space and the notch portion. This notch portion is adapted to uniformly spread the hologram recording material over the entire filling space so as to form a recoding layer having a substantially uniform thickness. That is, the notch portion defines a relief area for a part of the hologram recording material which has no destination when the recording material is pressed downward by the top substrate during a manufacture process of a hologram recording medium, thereby it is possible to enable the hologram recording material to have a substantially uniform thickness in a part constituting an information recording zone (filling space).

It is noted that the bottom substrate may be integrally incorporated with the frame or may be bonded thereto with the use of an adhesive or the like.

It is preferable to set the size of the top substrate to be smaller than that of the inner peripheral part of the frame in order to press the hologram recording material by the top substrate since the thickness of the hologram recording material is defined by a depressing pressure of the top substrate during the manufacture process of the hologram recording medium.

Further, the top and bottom substrates and the frame are rectangular, and accordingly, the recording medium has a rectangular shape in its entirety. In the case of the hologram recording medium having a rectangular shape, it is preferable to provide the notch portion at each of the four corners although one notch portion formed at at least one of the four corners is sufficient.

Moreover, according to the present invention, there is provided a hologram cartridge media in which the above-mentioned hologram recording medium is accommodated. In this case, the hologram cartridge media is composed of a hologram recording medium having any one of the above-mentioned configurations, a cartridge base for accommodating therein the hologram recording medium, having a window frame for exposing therefrom at least a part of the hologram recording medium which serves as a recording surface, a cartridge cover for enclosing the hologram recording medium in cooperation with the cartridge base. Further, there may be provided a sealing film for preventing moisture absorption, adapted to be interposed between the hologram recording medium and the cartridge. Further, the sealing film for preventing moisture absorption may be formed thereover with a reflective coating.

Further, the cartridge base may be formed therein with a positioning part (for example, a notch) for positioning the cartridge media upon loading of the latter into a drive unit.

Further, the cartridge cover may be marked with an arrow for indicating the direction of loading the cartridge into the drive unit.

The further features, objects and advantages of the present invention will be apparent in view of the following best modes of the present invention for carrying out the present invention, with reference to the accompanying drawings.

According to the present invention, there may be provided a hologram recording medium in which a hologram recording material is uniformly filled over substrates at every nook and corner of the latter, and a hologram cartridge media accommodating therein the hologram recording medium.

Explanation will be specifically made of embodiments of the hologram recording medium according to the present invention, with reference to the accompanying drawings. The configuration shown in the accompanying drawings is a mere example of the present invention, and accordingly, the present invention should not be limited to this configuration.

### BRIEF DESCRIPTION OF THE SEVERAL VIEWS OF THE DRAWINGS

FIG. 1 is a view illustrating an example of a configuration of a conventional hologram recording medium;

FIG. 2A is a view for illustrating a configuration of a hologram recording medium in accordance with an embodiment of the present invention;

FIG. 2B is a detailed view illustrating a part 2B in FIG. 2A;

FIGS. 3A to 3C are schematic views for explaining manufacturing steps of the hologram recording medium in accordance with the embodiment of the present invention;

FIGS. 4A to 4F are views for explaining steps of incorporating the hologram recording medium according to the embodiment of the present invention, into a cartridge;

FIG. 5A is a schematic view illustrating an external appearance of a hologram cartridge media according to an embodiment of the present invention;

FIG. 5B is a detailed view illustrating a part 5B in FIG. 5A;

FIG. 5C is a schematic view illustrating a rear surface of the cartridge media shown in FIG. 5A;

FIG. 6A is a schematic view illustrating a configuration of a hologram recording medium in accordance with another embodiment of the present invention; and

FIG. 6B is a plan view illustrating the hologram recording medium shown in FIG. 6A.

### DETAILED DESCRIPTION OF THE INVENTION

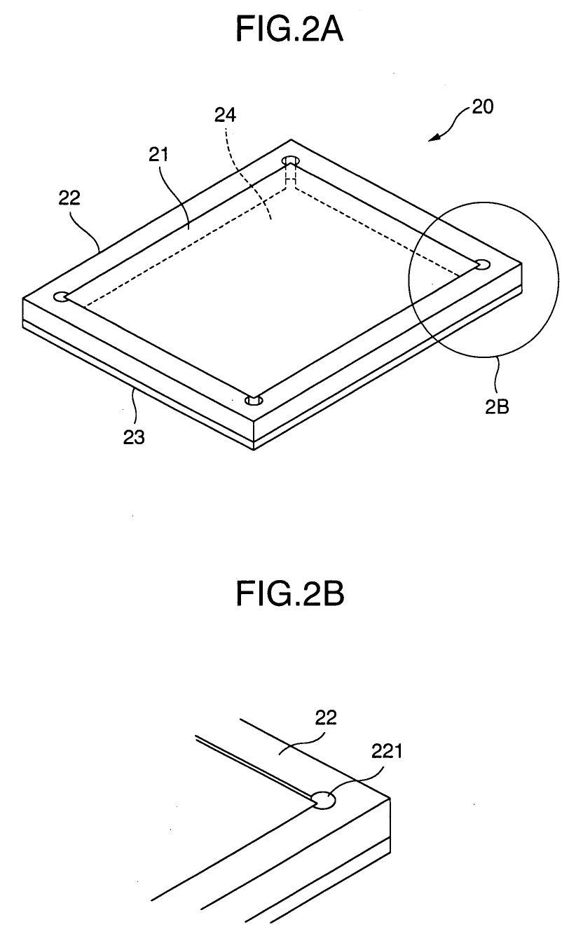

FIG. 2A is a view illustrating an external appearance of a hologram recording medium 20 according to an embodiment of the present invention, the hologram recording medium 20 shown in FIG. 2A is composed of a top substrate 21, a frame 22 a bottom substrate 23, and a hologram recording material 24 which is filled in a hologram recording material filling space defined by the above-mentioned components. The bottom substrate 23 has a size which is larger than the inner peripheral size of the frame 22 but not greater than the outer peripheral size of the latter. The top substrate 21 has a size which is slightly smaller than the inner peripheral size of the frame 22, and accordingly, it can be fitted in the frame 22. Further, as shown in FIG. 2B, notch portions are formed in the frame 22, respectively at four corners thereof, and define material trapping parts 221 in which the hologram recording material 24 is trapped after it is pressed by the top substrate 21 so as to be spread over the entire surface of the substrate. Since the material trapping parts 221 are filled therein with extra hologram recording material, the hologram recording material can be uniformly filled in a data recording zone (filling space) with substantially uniform thickness. These notch portions may be formed, irrespective of whether it pierces through the frame 22 from a top surface to a bottom surface of the latter or not, if they can serve as places into which the extra hologram material escapes.

It is noted that the material trapping parts 221 are formed in the rectangular hologram recording medium 20 at four corners of the latter. However, the present invention should not be limited to this configuration, but they may be formed at two diagonal corners thereof or may be formed at any arbitrary position of four sides thereof (at least one side thereof).

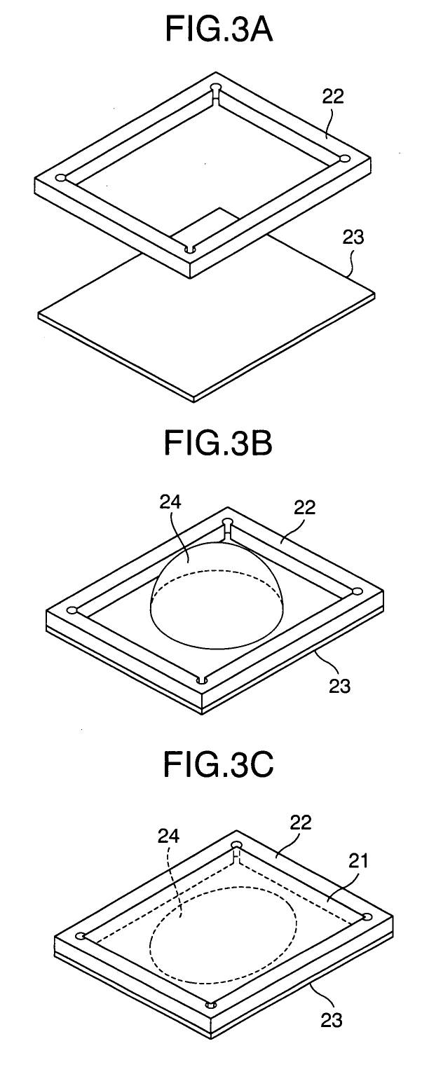

Next, explanation will be made of process steps of manufacturing the hologram recording medium 20. FIGS. 3A to 3C are schematic views for explaining the manufacturing process steps of the hologram recording medium 20 having the configuration shown in FIGS. 2A to 2B.

Referring to FIG. 3A, at first, the frame 22 is set on the bottom substrate 23, and they are bonded to each other by means of an adhesive or the like. The frame 22 and the bottom substrate 23 may be integrally incorporated with each other. In this state, the hologram recording material 24 is filled in the frame 22 in a predetermined quantity (refer to FIG. 3B). Then, the hologram recording material 24 which is viscous is depressed and spread out by the top substrate 21 so that the hologram recording material 24 is uniformly widespread in the filling space (refer to FIG. 3C). It is noted that the filling quantity of the hologram recording material 24 is set to be slightly larger than a quantity required for forming a recording layer having a desired thickness in the recording material filling space defined by the top and bottom substrates 21, 23 and the frame 22. That is, a material which is surplus to the quantity required for forming the recording layer having a desired thickness, can escape into the material trapping parts 221 upon the depression of the top substrate 21. Accordingly, no delicate adjustment for the depressing pressure and the filling quantity of the hologram recording material 24 are required, and accordingly, the productivity of the hologram recording medium 20 can be enhanced. Further, in the recording material filling space, the hologram recording material for forming the recording layer has a thickness which may be substantially uniform (it is noted that the hologram recording material cannot have a precisely uniform thickness, and accordingly, the wording “substantially” is used. Thus, the wording should not be construed as such that the concept of the present invention is ambiguous). For example, if the thickness of the top and bottom substrates is set to 0.8 mm while the thickness of the recording medium is set to 1.5 mm, the thickness of the frame may be set to at least 2.3 (=1.5+0.8) mm.

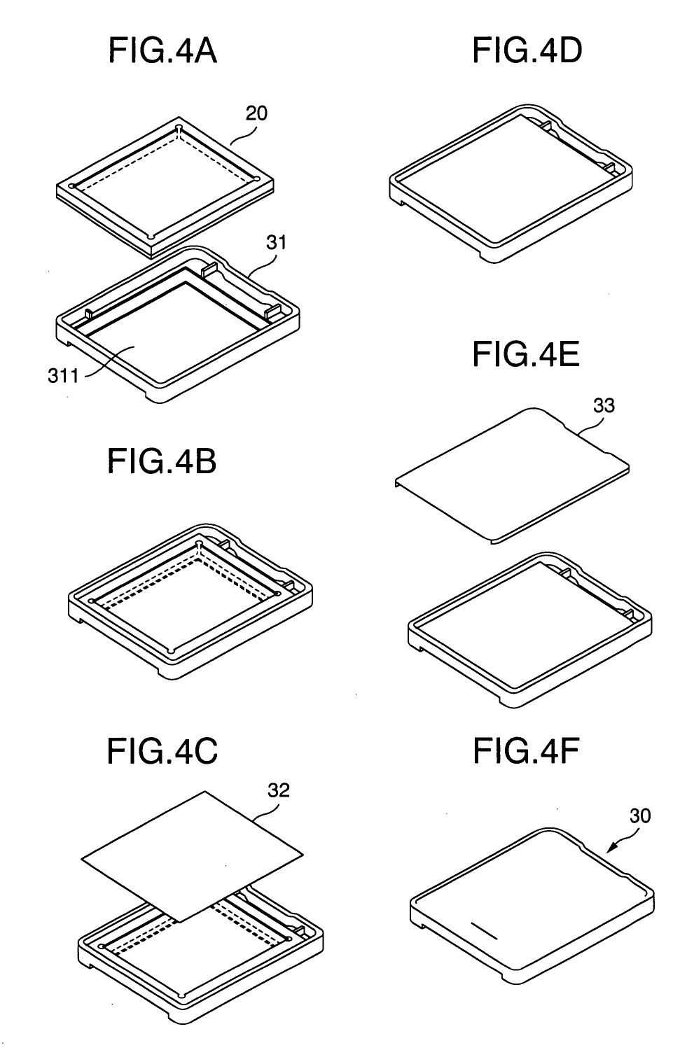

The hologram recording medium 20 manufactured as stated above, is incorporated in a cartridge, and accordingly, a final product is obtained. FIGS. 4A to 4F are schematic views for explaining process steps of incorporating the hologram recording medium 20 into the cartridge.

Referring to FIGS. 4A to 4F, the hologram recording medium 20 is set in a cartridge base 31 having a window frame 311 in such a way that the bottom substrate 23 is fitted in the window frame 311. Further, in this state, a reflective and moisture-proof sealing film 32 is set on the top substrate 21 (refer to FIGS. 4C and 4D). In this condition in which the moisture-proof sealing film 32 is set, the cartridge cover 33 is laid over the film 32, and accordingly, a hologram cartridge media 30 is obtained as a final product (refer to FIGS. 4E and 4F). It is noted that the sealing film 32 may be further coated with a reflective film so as to have a function for reflecting a reference beam in such a case that the hologram recording media 30 is exclusively used as a ROM.

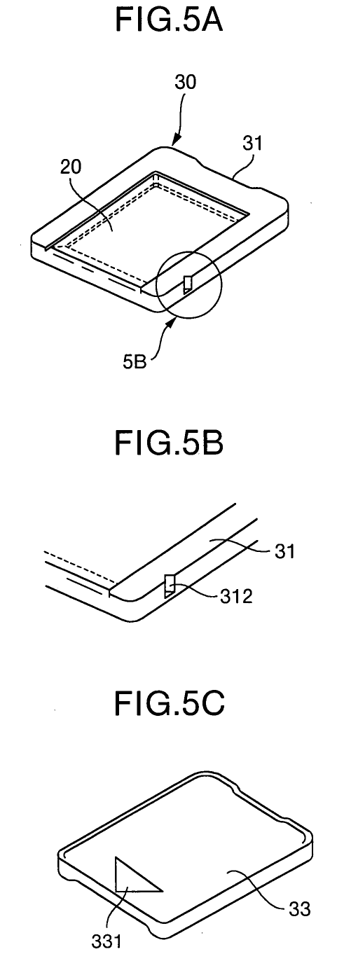

FIGS. 5A to 5C show an external appearance of the hologram cartridge media 30 manufactured as stated above. Referring to FIG. 5A which shows the front surface (recording surface) of the cartridge, recording and reproduction of information are carried out for the hologram recording medium 20 which is exposed from the window frame 311. That is, in a recoding and reproducing apparatus which is not shown, an interference pattern (interference fringes) which is formed through the interference between an information beam (two-dimensional data) and a reference beam is three-dimensionally formed in the hologram recording medium during information recording. Further, during information reproduction, the reference beam used for the information recording is irradiated onto the interference pattern so as to generate a reproduction beam which is then decoded for information reproduction.

As shown in FIG. 5B which is an enlarged view illustrating a part 5B in FIG. 5A, a notch 312 is formed in the cartridge base 31, with which the positioning of the hologram cartridge media 30 is carried out in a recording and reproducing apparatus (drive unit) which is not shown. Referring to FIG. 5C which shows the rear surface of the cartridge media, the cartridge cover 33 as shown is marked with an arrow (which may be integrally formed therewith) for indication of a direction of loading the hologram cartridge media 30 into the recording and reproducing apparatus. This arrow 331 exhibit such an advantage the user can prevent the cartridge media from being loaded in an erroneous direction.

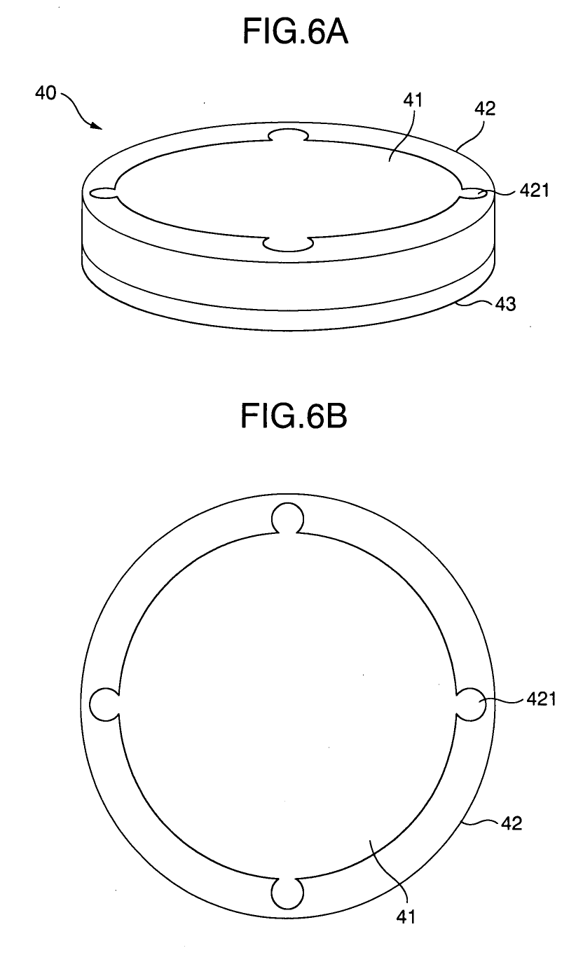

Although explanation has been hereinabove made of the polygonal (rectangular) hologram recoding medium 20 in which the material trapping parts are formed, it is noted that the hologram recording medium 20 should not be limited to a rectangular shape in such a case that the recording capacity may be equal to the conventional one, that is, it may have a conventional disc shape. Referring to FIGS. 6A and 6B which are views illustrating a configuration of a disc shape hologram recording medium 40, at least one material trapping part 421 is formed in the inner peripheral part of the frame 42. With this configuration, even with the disc shape hologram recording medium, the hologram recording material (photopolymer material) which is viscous, may be filled so as to be uniformly spread into every corner of the substrates.

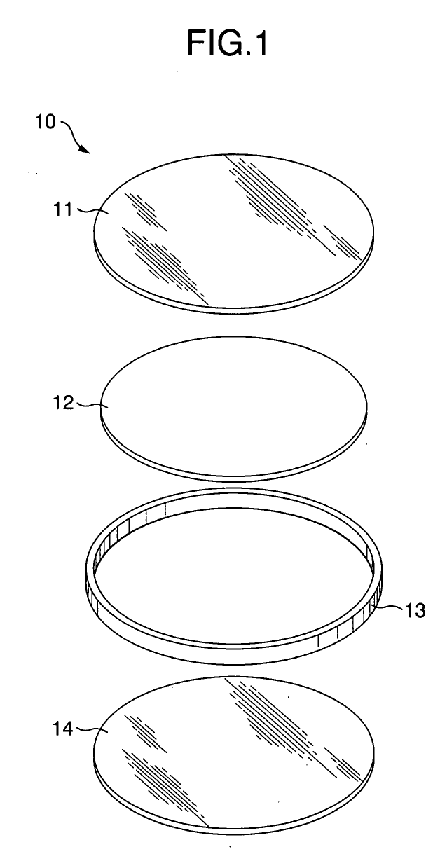

Further, in the embodiment shown in FIGS. 1 to 5C, there may be formed the hologram recording medium as follows: the frame 22 is integrally formed with or bonded to the cartage base 31, then, the bottom substrate 23 is attached to the cartridge base 31 so as to cover the window frame 331 underneath thereof, and the hologram recording material is filled in the filling space (filling zone) defined by the bottom substrate 23 and the frame 22.

The hologram recording medium according to the embodiment of the present invention is formed by filling a hologram recording material such as photopolymer between the top and bottom planar substrates. Further, the frame for ensuring a filling space for the hologram recording material is interposed between the top and bottom substrates. The frame has at least one notch portion formed in its inner peripheral part, and accordingly, the hologram recording material is filled in the notch portion and the filling space. The notch portion allows the hologram recording material to be uniformly spread over in the filling space in its entirety, and to form a recording layer having a substantially uniform thickness. That is, the notch portion serves as a place where a surplus hologram recording material which has no destination since the hologram recording material is depressed by the top substrate escapes during the manufacturing process of the hologram recording medium. Thus, the hologram recording material can have a uniform thickness in a part which constitutes of an information recording zone (the filling space). With the provision of the notch portion (the material trapping part or the material relief part), a hologram recording medium which can eliminate a problem of inferior filling of the material can be materialized. Further, with the notch portion, the regulation for the thickness can be facilitated, and accordingly, a hologram recording medium having no unevenness in thickness, that is, having a precise thickness can be materialized.

It is noted that the bottom substrate may be integrally incorporated with the frame or may be bonded thereto by means of an adhesive. In particular, the integral incorporation thereof can completely prevent occurrence of such a risk that the hologram recording material leaks through a gap between the bottom substrate and the frame.

In order to allow the top substrate to depress the hologram recording material, it is desirable that the top substrate has a size which is smaller than the size of the inner peripheral part of the frame since the thickness of the hologram recording material is defined by the depressing pressure of the top substrate during the manufacturing step. Thus, it is possible to form a recording layer having a predetermined thickness.

Further, the top and bottom substrate and the frame are rectangular and accordingly, the recording medium has rectangular shape in its entirety. Thus, the recording medium accommodated even in a cartridge may have an increased recording capacity in comparison with a disc shape recording medium. In the case of the configuration of a rectangular hologram recording medium, a notch portion may be formed in at least one corner of the frame, but it is more preferably to form the notch portion in each of the four corners of the frame.

In the embodiments of the present invention, there is provided a hologram cartridge media accommodating therein the above-mentioned hologram recording medium. In this case, the hologram cartridge media comprises a hologram recording medium having any one of the configurations as stated above, a cartridge base accommodating the hologram recording medium therein and having a window frame through which at least a part of the hologram recording medium is exposed so as to serve as a recording surface, and a cartridge cover for enclosing the hologram recording medium in cooperation with the cartridge base. The hologram cartridge media can prevent the hologram recording medium enclosed therein from being optically sensitized. Thus, there may be provided a recording medium which is convenient in use for the user. Further, with the incorporation of the moisture-proof sealing film interposed between the hologram recoding medium and the cartridge, the environmental resistance thereof can be enhanced. It is noted that moisture-proof sealing film may be applied thereover with a reflective coating in the case of the provision of a hologram recording medium exclusively used as a ROM. This reflective film can reflect a reference beam during the information reproduction.

Further, with the provision of the cartridge base formed therein with a notch for positioning the cartridge media in a drive unit during loading thereof, the positioning of the cartridge media can be precisely carried out during recording and reproduction even with a simple configuration.

Further, with the provision of the cartridge cover marked with an arrow for indication of a direction of loading the cartridge media, there can be prevent such a risk that the user loads the cartridge media in an erroneous direction.

1. A hologram recoding medium in which a hologram recording material is filled between planar substrates, comprising:
a top substrate,
a bottom substrate, and
a frame interposed between said top substrate and said bottom substrate and defining therein a filling part for said hologram recording material,
wherein said frame has at least one notch portion formed in an inner peripheral part thereof, and said hologram recording material is filled in said filing space and as well in said notch portion.

2. The hologram recording medium as set forth in claim 1, wherein said filling space corresponds to an information recording zone in which an interference pattern is reproduced, and said hologram recording material is filled so as to have substantially uniform thickness at least in said filling space.

3. The hologram recording medium as set forth in claim 1, wherein the bottom substrate is integrally incorporated with said frame.

4. The hologram recording medium as set forth in claim 1, wherein said top substrate has a size which is smaller than that of the inner peripheral part of said frame, and a thickness of said hologram recording material is defined by a depressing pressure of said top substrate during a manufacturing process of said hologram recording medium.

5. The hologram recording medium as set forth in claim 1, wherein both top and bottom substrates are rectangular.

6. The hologram recording medium as set forth in claim 5, characterized in that the cutout is formed at each of the four corners of the frame.

7. A hologram cartridge media incorporating therein a hologram recording medium, comprising:
a hologram recording medium as set forth in claim 1,
a cartridge base accommodating therein said hologram recording medium, and having a window frame from which at least a part of the hologram recording medium is exposed, which serves as a recording surface, and
a cartridge cover for enclosing said hologram recording medium in cooperation with said cartridge base.

8. The hologram cartridge media as set forth in claim 7, further comprising a moisture-proof sealing film interposed between said hologram recording medium and said cartridge media.

9. The hologram cartridge media as set forth in claim 8, wherein said moisture-proof sealing film is applied thereover with a reflective coating.

10. The hologram cartridge media as set forth in claim 7, wherein said cartridge base is provided with a positioning part for positioning said cartridge media in a drive unit.

11. The hologram cartridge media as set forth in claim 7, wherein said cartridge cover is marked with an arrow for indication of a direction of loading said hologram cartridge media into a drive unit.
